(19) United States
(12) Patent Application Publication
(10) Pub. No.: US 2024/0019496 A1
(43) Pub. Date: Jan. 18, 2024

(54) METHOD, APPARATUS, AND DEVICE FOR PREDICTING CAPACITY OF POWER BATTERY

(71) Applicant: BYD COMPANY LIMITED, Shenzhen (CN)

(72) Inventors: Linwang DENG, Shenzhen (CN); Tianyu FENG, Shenzhen (CN); Pengqing ZHANG, Shenzhen (CN); Xiaoqian LI, Shenzhen (CN)

(21) Appl. No.: 18/373,821

(22) Filed: Sep. 27, 2023

Related U.S. Application Data
(63) Continuation of application No. PCT/CN2022/099307, filed on Jun. 17, 2022.

(30) Foreign Application Priority Data
Jun. 25, 2021 (CN) 202110711103.9

(51) Int. Cl. G01R 31/367; G01R 31/392; G01R 31/387; G01R 31/374

(52) U.S. Cl. CPC G01R 31/367; G01R 31/392; G01R 31/387; G01R 31/374

(57) ABSTRACT

A method for obtaining a capacity of a power battery includes: collecting, by sensors, sample data of the power battery; dividing, by a processor, the sample data into multiple categories, each of the categories having a corresponding aging model and a feature identifier, the feature identifier identifying features of sample data of a corresponding category, and the aging model being obtained by: determining a fitting relationship in the aging model, and determining parameters in the fitting relationship according to sample data of a corresponding type of the aging model; acquiring, by the processor, battery state parameters of the power battery; selecting, by the processor, an aging model from multiple aging models according to the battery state parameters; and inputting, by the processor, the battery state parameters into the selected aging model to obtain the capacity of the power battery.

### CROSS-REFERENCE TO RELATED APPLICATIONS

This application is a Continuation application of International Patent Application No. PCT/CN2022/099307, filed on Jun. 17, 2022, which is based on and claims priority to and benefits of Chinese Patent Application No. 202110711103.9, filed on Jun. 25, 2021. The entire content of all of the applications is incorporated herein by reference.

### FIELD

The present disclosure relates to the technical field of battery management, and more particularly, to a method for predicting/obtaining a capacity of a power battery, an apparatus for predicting/obtaining a capacity of a power battery, a device for predicting/obtaining a capacity of a power battery, and a corresponding computer-readable storage medium.

### BACKGROUND

A power battery is an important component of an electric vehicle. Lifespan is a major performance index of the power battery. Accurately predicting the lifespan not only helps to understand the degradation status of the battery, provide accurate vehicle operating status information for a user, and provide a basis for cost calculation in vehicle production and manufacturing, but also helps to prevent the occurrence of faults and disasters, thereby ensuring the safety of life and property of the user.

The lifespan of the power battery is typically estimated by an experimental method and a model method.

In the experimental method, during the actual operation of the vehicle, the current of the power battery is not constant, leading to inaccurate prediction results. In addition, standard new European driving cycle (NEDC) conditions may be adopted to simulate actual working conditions for discharge testing, but the test cycle is too long.

The model method mainly adopts a mechanism model and a statistical model. The mechanism model includes an electrochemical analysis method, an impedance method, etc. The statistical model mainly refers to a lifespan prediction model designed based on a neural network, such as a lifespan prediction method based on a long short-term memory (LSTM) neural network and transfer learning, and a deep learning method for predicting lifespan of lithium batteries. Actual vehicle driving conditions are complex, mechanism model parameters are hard to acquire, and it is difficult to accurately predict the battery lifespan.

### SUMMARY

In view of this, the present disclosure proposes a method, apparatus, and device for obtaining a capacity of a power battery to at least partially solve the problems that in related arts of a long experimental method in test cycle, parameters in a model method being hard to acquire, and a high model complexity.

In order to achieve the above objectives, the present disclosure provides a method for predicting a capacity of a power battery. The prediction method includes: collecting, by sensors, sample data of the power battery; dividing, by a processor, the sample data into multiple categories, each of the categories having a corresponding aging model and a feature identifier, the feature identifier identifying features of sample data of a corresponding category, and the aging model being obtained by: determining a fitting relationship in the aging model, and determining parameters in the fitting relationship according to sample data of a corresponding type of the aging model; acquiring, by the processor, battery state parameters of the power battery; selecting, by the processor, an aging model from multiple aging models according to the battery state parameters; and inputting, by the processor, the battery state parameters into the selected aging model to obtain the capacity of the power battery.

According to an embodiment of the present disclosure, the sample data of the power battery includes: multiple sets of data for the same model of the power battery under multiple vehicle driving conditions.

According to an embodiment of the present disclosure, the step that the sample data is divided into multiple categories includes the following: selecting a clustering algorithm, and determining clustering parameters in the clustering algorithm; categorizing each point of the sample data as a core point or a boundary point of a cluster according to the clustering parameters; and configuring the categories according to the core point, and dividing the sample data into the categories.

According to an embodiment of the present disclosure, the clustering algorithm is a Density-Based Spatial Clustering of Applications with Noise (DBSCAN) algorithm; and the clustering parameters include a radius of neighborhood and a neighborhood count threshold.

According to an embodiment of the present disclosure, the feature identifier includes a clustering center. The step that selecting an aging model corresponding to the battery state parameters from multiple aging models includes: calculating a distance between the battery state parameters and a clustering center corresponding to each of the categories; and selecting an aging model having a shortest distance as the aging model corresponding to the battery state parameters.

According to an embodiment of the present disclosure, the fitting relationship includes polynomial fitting, neural network fitting, or regression tree fitting.

According to an embodiment of the present disclosure, the battery state parameters include: at least two of a current, a voltage, a temperature, state of charge, storage time, a depth of discharge, and coulombic efficiency.

In a second aspect of the present disclosure, an apparatus for obtaining a capacity of a power battery is further provided, which includes: an input unit, configured to collect battery state parameters; a matcher, configured to be matched with the battery state parameters, so as to determine an aging model corresponding to the battery state parameters from multiple aging models, where the multiple aging models are in one-to-one correspondence with multiple categories of sample data divided according to a clustering algorithm, and each of the aging models includes a mapping relationship between the battery state parameters and the battery capacity; and a calculator, configured to input the battery state parameters into the aging model, to obtain the capacity of the power battery.

In a third aspect of the present disclosure, a device for obtaining a capacity of a power battery is further provided, and includes: at least one processor, and a memory coupled with the at least one processor. The memory stores, and when the instructions are executed by the at least one processor, the instructions cause the at least one processor to implement a foregoing method for obtaining a capacity of a power battery of the first aspect.

In a fourth aspect of the present disclosure, a non-transitory computer-readable storage medium is further provided, the medium stores a computer program. The computer program, when executed by a processor, causes the processor to implement a foregoing method for obtaining a capacity of a power battery of the first aspect.

Features and advantages of the present disclosure will be described in detail in the following detailed description part.

### BRIEF DESCRIPTION OF THE DRAWINGS

The accompanying drawings constituting a part of the present disclosure are used for providing further understanding of the present disclosure. Some implementations of the present disclosure and descriptions thereof are used for explaining the present disclosure, and do not limit the present disclosure. In the accompanying drawings:

FIG. 1 is a schematic flowchart of a method for predicting a capacity of a power battery according to the implementation of the present disclosure;

FIG. 2 is a flowchart of a clustering algorithm in a method for predicting a capacity of a power battery according to the implementation of the present disclosure;

FIG. 3 is a schematic diagram of calculation of clustering center distances in a method for predicting a capacity of a power battery according to the implementation of the present disclosure;

FIG. 4 is a schematic flowchart of an implementation of a method for predicting a capacity of a power battery according to the implementation of the present disclosure; and

FIG. 5 is a schematic structural diagram of an apparatus for predicting a capacity of a power battery according to the implementation of the present disclosure.

### DETAILED DESCRIPTION

It is to be noted that, implementations in the present disclosure and features in the implementations may be combined with each other in the case of no conflict.

The present disclosure is described in detail with reference to the accompanying drawings and in combination with the implementations as below.

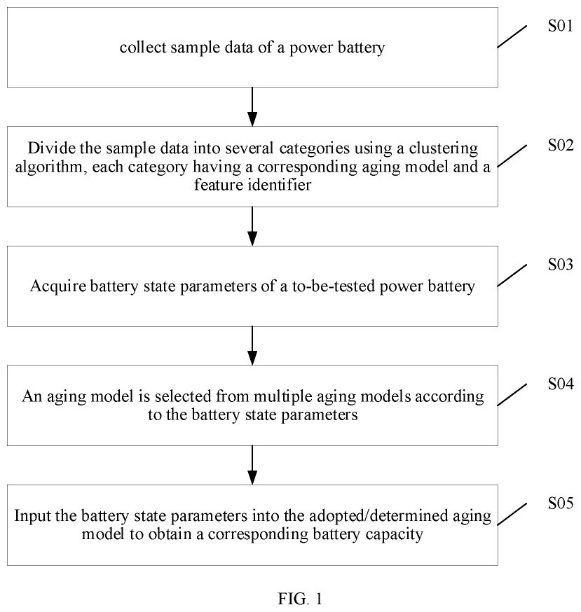

FIG. 1 is a schematic flowchart of a method for predicting a capacity of a power battery according to the implementation of the present disclosure, as shown in FIG. 1. A method for predicting a capacity of a power battery is provided. The prediction method includes the following:

S01: Sample data of the power battery is acquired/collected.

The sample data can be acquired (e.g., by sensors) from the power battery under actual vehicle driving conditions, and the sample data can include current I, voltage V, temperature T, state of charge SOC, storage time t, depth of discharge DOD, and coulombic efficiency u, or a combination of parameters selected therefrom.

S02: The sample data is divided into several categories using a clustering algorithm, and each category determines a corresponding aging model and a feature identifier. The aging model is obtained by the following steps: a fitting relationship in the aging model is determined, and parameters in the fitting relationship are determined according to sample data of the corresponding type of the aging model. The feature identifier is used for identifying features of the sample data of the corresponding category.

The sample data is classified, and each category of sample data has a certain similarity or intrinsic correlation. By classifying the sample data through the clustering algorithm, a classification result can be rapidly obtained, and the classification result is desirable. The clustering algorithm may be selected from existing clustering algorithms according to actual needs. The aging model is required to be determined for each category. The aging model is a mathematical model, and first, a fitting relationship in the mathematical model is determined, that is, to select an appropriate fitting function. Then, the fitting relationship is trained or corrected by the sample data within the category, so as to determine the parameters in the fitting relationship, and thus, the aging model for calculating the battery capacity based on input parameters is obtained.

S03: Battery state parameters of the to-be-tested power battery are acquired.

The battery state parameters acquired herein serve as input parameters for predicting capacity, which contain the parameters that are the same as or have a subset relationship with the parameters in the sample data in step S01.

S04: An aging model is selected from multiple aging models according to the battery state parameters.

First, the aging model is determined according to the battery state parameters. Based on the same battery state parameters, different battery capacities may be obtained according to different aging models. In this implementation, the aging model is determined according to the feature identifier. By determining the appropriate aging model, the battery capacity can be calculated more accurately.

S05: The battery state parameters are input into the adopted/determined aging model to obtain a corresponding battery capacity. The aging model adopted in this step is the aging model determined in step S04, and is configured to obtain the corresponding battery capacity according to the battery state parameters, that is, the corresponding battery capacity can be obtained by inputting the battery state parameters.

Through the above implementation, multiple aging types can be distinguished, and thus, the corresponding aging models are established according to different aging types, thereby improving precision of the aging models, and more accurately predicting the capacity of the power battery. When the sample data becomes more abundant, there are an increasing number of different aging types of data and a wider coverage of different aging types, the clustering algorithm can distinguish different categories more comprehensively, and a distinguishing effect is more intuitive and reliable.

In an implementation provided by the present disclosure, the sample data of the power battery includes: multiple sets of historical data for the same model of power battery under actual vehicle driving conditions. The historical data under the actual vehicle driving conditions is adopted as samples, which can better reflect real scenarios and facilitate the acquisition of a large number of samples. Through a large number of sample data that reflects the actual state of multiple power batteries, the defects of the experimental method and the model method are overcome, which can make clustering more accurate and thus make the predication of the battery capacity more accurate.

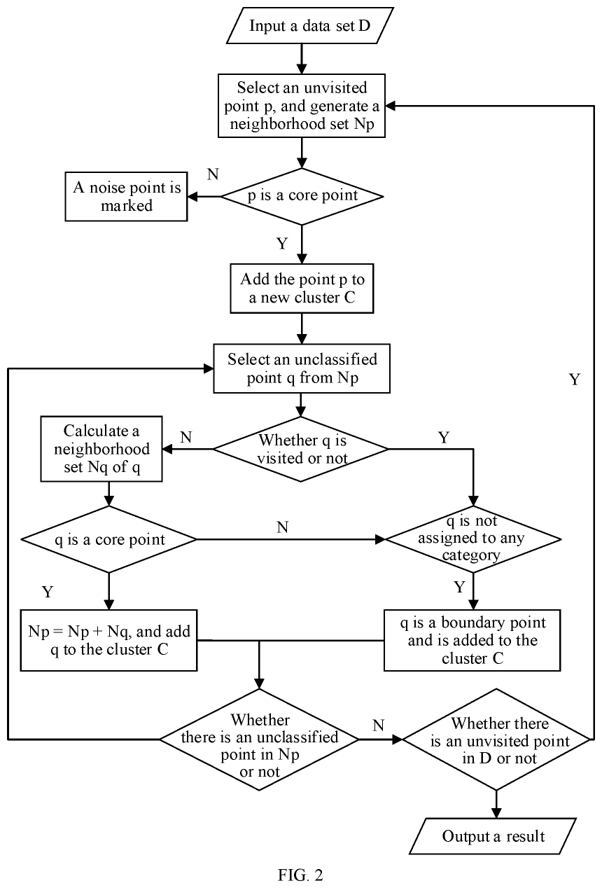

FIG. 2 is a flowchart of a clustering algorithm in a method for predicting a capacity of a power battery according to the implementation of the present disclosure, as shown in FIG. 2. In this implementation, the step that the sample data is divided into several categories by using a clustering algorithm includes the following: the clustering algorithm is preset or selected, and clustering parameters in the clustering algorithm are determined. The points of the sample data are divided into core points or boundary points according to the clustering parameters. Categories are constructed according to the core points, and the sample data is divided into the several categories. Further, the clustering algorithm is a DBSCAN algorithm; and the clustering parameters include a radius of neighborhood Eps and a neighborhood count threshold Minpts. A clustering process is as below: in an embodiment, a data set is first scanned, an unvisited point p is selected, and a neighborhood set Np is generated. If the count of the points within Eps(p) is greater than Minpts, p is determined as a core point, and a new cluster C is generated. Then, an unclassified point q in Np is selected. If q is not visited, a neighborhood set Nq is generated. If the count in Eps(q) is greater than Minpts, q is determined as a core point, and Np is updated as Np=Np+Nq. The point q is added to the cluster C. If q is neither the core point nor assigned to any category, and q is determined as a boundary point to be added to the cluster C. The process continues until Np no longer contains unclassified points. Following this process, if there are still unvisited points in the data set D, the second step is repeated, and an unvisited point is selected. Through the above method, the sample data is divided into the foregoing several categories.

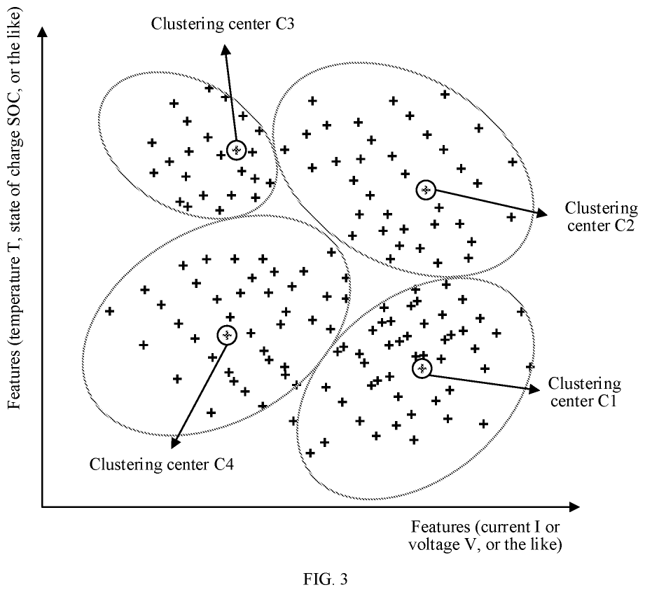

FIG. 3 is a schematic diagram of calculation of clustering center distances in a method for predicting a capacity of a power battery according to the implementation of the present disclosure, as shown in FIG. 3. In this implementation, feature identifiers are clustering centers. The step that an aging model adopted by the battery state parameters is determined from multiple aging models includes the following: a distance between the battery state parameters and a clustering center corresponding to each category is calculated, and a nearest aging model (e.g., the aging model have the shortest distance) is selected as the aging model corresponding to the battery state parameters. The figure only shows the situation of four clustering centers C1-C4, and the number of the clustering centers does not limit the number of types. Common clustering calculations in clustering analysis include Euclidean distance, Manhattan distance, Chebyshev distance, and the like, which are primarily used for measuring similarity. By the calculation according to the above method, the similarity (distance) between two objects can be obtained. In the practical calculation, effective selection is performed according to attribute characteristics of different objects. The calculation of the distance between the objects in the clustering algorithm process may directly affect the effectiveness of the algorithm, and thus, selection is required to be careful when making practical selections.

In an implementation provided by the present disclosure, the fitting relationship includes polynomial fitting, neural network fitting, or regression tree fitting. The polynomial fitting includes: y=p_{0}x\hat{ }n+p_{1}x\hat{ }{n−1}+p_{2}x\hat{ }{n−2}+p_{3}x\hat{ }{n−3}+ . . . +p_{n}. The number of terms in the polynomial may be determined as needed. The neural network fitting includes: a convolutional neural network (CNN), a recurrent neural network (RNN), a generative adversarial network (GAN), etc. By selecting an appropriate neural network structure and training the neural network structure with sample data, an aging model which can predict the battery capacity can be obtained. The regression tree fitting includes common binary trees. For example, a binary tree is used for recursively dividing a prediction space into several subsets, and the distribution of Y within these subsets is continuous and uniform. Leaf nodes in the tree correspond to different divided regions, and the division is determined by splitting rules associated with each internal node. By traversing from the root to the leaf nodes, a prediction sample is assigned with a unique leaf node, and the conditional distribution of Y at this node is also determined. Methods for establishing of different aging models are not repeated herein.

In an implementation provided by the present disclosure, the battery state parameters include: at least two of a current, a voltage, a temperature, state of charge, storage time, a depth of discharge, and coulombic efficiency. The more input parameters there are, the more accurate the obtained battery capacity will be. In a scenario, those skilled in the art select, based on practical conditions and measurement conditions, at least two of the above battery state parameters for combination, to obtain a more accurate battery capacity.

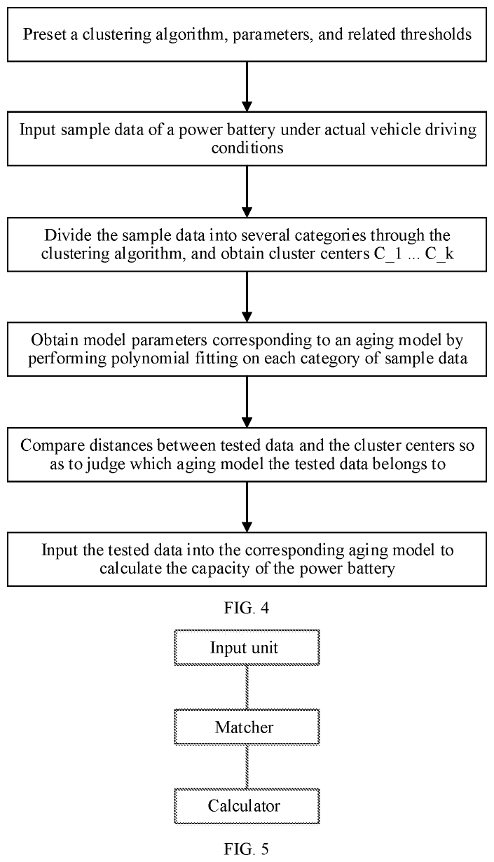

FIG. 4 is a schematic flowchart of an implementation of a method for predicting a capacity of a power battery according to the implementation of the present disclosure, as shown in FIG. 4. In this implementation, the method for predicting a capacity of a power battery includes following steps:

(1) The clustering algorithm, parameters and related thresholds are preset.

(2) The sample data of the power battery under actual vehicle driving conditions is input.

(3) The sample data is divided into several categories through the clustering algorithm, and clustering centers C1, . . . , Ck are obtained.

(4) Model parameters corresponding to an aging model are obtained by performing a statistical model such as polynomial fitting, neural network fitting, and regression tree fitting on each category of sample data.

Cap=f(I,V,T,SOC,t,DOD,μ)

(5) Distances between to-be-tested data and the clustering centers are compared so as to determine which aging model the to-be-tested data belongs to.

(6) The to-be-tested data is input into the corresponding aging model to calculate the capacity of the power battery.

FIG. 5 is a schematic structural diagram of an apparatus for predicting/obtaining a capacity of a power battery according to the implementation of the present disclosure, as shown in FIG. 5. In this implementation, the apparatus for predicting a capacity of a power battery includes: an input unit, configured to acquire battery state parameters; a matcher, configured to be matched with the battery state parameters, so as to determine an aging model adopted by the battery state parameters from multiple aging models, where the multiple aging models are in one-to-one correspondence with several categories of sample data divided according to a clustering algorithm, and each of the aging models includes a mapping relationship between the battery state parameters and the battery capacity; and a calculator, configured to input the battery state parameters into the adopted aging model, to obtain the corresponding battery capacity.

The limitations on various modules (the input unit, the matcher, and the calculator) in the apparatus for predicting a capacity of a power battery may be referred to the limitations on a method for predicting a capacity of a power battery in the above, which are not repeated herein. The various modules in the above apparatus may be all or partly implemented by software, hardware, and a combination thereof. The above various modules may be embedded in or independent of a processor in a computer device in a hardware form, and may also be stored in a memory of the computer device in a software form, so that the processor can call and execute the corresponding operations of the various modules.

In an implementation provided by the present disclosure, a device for predicting a capacity of a power battery is further provided, and includes: at least one processor, and a memory connected/coupled with the at least one processor. The memory stores instructions executable by the at least one processor, and the at least one processor implements a foregoing method for predicting a capacity of a power battery by executing the instructions stored in the memory. The controller or processor mentioned herein has the functions of numerical computation and logical operations, and at least has a central processing unit (CPU) with the data processing capability, a random access memory (RAM), a read-only memory (ROM), multiple I/O ports, and an interrupt system, etc. The processor includes a core, and the core invokes a corresponding program unit from the memory. There may be one or more cores, and the foregoing method is implemented by adjusting core parameters. The memory may include forms such as a volatile memory, the random access memory (RAM), and/or a non-volatile memory, such as the read-only memory (ROM) or a flash memory (flash RAM) in a computer-readable medium.

In an implementation provided by the present disclosure, a computer-readable storage medium (e.g., a non-transitory computer-readable storage medium) stores a computer program. The computer program, when executed by a processor, implements a foregoing method for predicting a capacity of a power battery.

Those skilled in the art should understand that the embodiments of the present disclosure may be provided as a method, a system, or a computer program product. Therefore, the present disclosure may use a form of hardware-only embodiments, software-only embodiments, or embodiments combining software and hardware. In addition, the present disclosure may use a form of a computer program product implemented on one or more computer-usable storage media (including but not limited to a disk memory, a CD-ROM, an optical memory, and the like) containing computer-usable program code.

The present disclosure is described with reference to flowcharts and/or block diagrams of the method, the device (system), and the computer program product in the embodiments of the present disclosure. It is be understood that computer program instructions can implement each procedure and/or block in the flowcharts and/or block diagrams, and a combination of procedures and/or blocks in the flowcharts and/or block diagrams. These computer program instructions may be provided to a general-purpose computer, a special-purpose computer, an embedded processor, or a processor of another programmable data processing device to generate a machine, so that an apparatus configured to implement functions specified in one or more procedures in the flowcharts and/or one or more blocks in the block diagrams is generated by using instructions executed by the computer or the processor of the another programmable data processing device.

These computer program instructions may alternatively be stored in a computer-readable memory that can instruct the computer or other programmable data processing device to work in a manner, so that the instructions stored in the computer-readable memory generate an artifact that includes an instruction apparatus. The instruction apparatus implements functions specified in one or more procedures in the flowcharts and/or in one or more blocks in the block diagrams.

These computer program instructions may further be loaded onto the computer or other programmable data processing device, so that a series of operations and steps are performed on the computer or other programmable device, thereby generating computer-implemented processing. Therefore, the instructions executed on the computer or other programmable device provide steps for implementing functions specified in one or more procedures in the flowcharts and/or in one or more blocks in the block diagrams.

In a typical configuration, the computer device includes one or more central processing units (CPUs), an input/output interface, a network interface, and an internal memory.

The memory may include forms such as the volatile memory, the random access memory (RAM), and/or the non-volatile memory, such as the read-only memory (ROM) or the flash memory (flash RAM) in the computer-readable medium. The memory is an example of the computer-readable medium.

The computer-readable medium includes a non-volatile medium and a volatile medium, a removable medium and a non-removable medium, which may implement storage of information by using any method or technology. The information may be a computer-readable instruction, a data structure, a program module, or other data. Examples of the storage medium of the computer include but not limited to a phase-change memory (PRAM), a static random access memory (SRAM), a dynamic random access memory (DRAM), or other types of random access memory (RAM), the read-only memory (ROM), an erasable programmable read-only memory (EEPROM), a flash memory or another storage technology, a compact disc read-only memory (CD-ROM), a digital versatile disc (DVD) or another optical storage, a cartridge tape, a magnetic tape, a magnetic disk storage or another magnetic storage device, or any other non-transmission medium, which may be configured to store information accessible by the computing device. According to limitations of this specification, the computer-readable medium does not include transitory computer-readable media, such as a modulated data signal and a modulated carrier.

It is to be further noted that, the term “include,” “comprise,” or their any other variants are to cover a non-exclusive inclusion, so that a process, a method, a product, or a device that includes a series of elements not only includes such elements, but also includes other elements not expressly listed, or further includes elements inherent to such a process, method, product, or device. Unless otherwise specified, an element limited by “include a/an . . . ” does not exclude other same elements existing in the process, the method, the product, or the device that includes the element.

The foregoing descriptions are merely the embodiments of the present disclosure, but are not to limit the present disclosure. For those skilled in the art, various modifications and variations can be made to the present disclosure. Any modification, equivalent replacement, improvement, etc. made within the spirit and principle of the present disclosure shall fall within the scope of the protection of the present disclosure.

What is claimed is:

1. A method for obtaining a capacity of a power battery, comprising:
collecting, by sensors, sample data of the power battery;
dividing, by a processor, the sample data into a plurality of categories, each of the categories having a corresponding aging model and a feature identifier, the feature identifier identifying features of sample data of a corresponding category, and the aging model being obtained by: determining a fitting relationship in the aging model, and determining parameters in the fitting relationship according to sample data of a corresponding type of the aging model;
acquiring, by the processor, battery state parameters of the power battery;
selecting, by the processor, an aging model from a plurality of aging models according to the battery state parameters; and
inputting, by the processor, the battery state parameters into the selected aging model to obtain the capacity of the power battery.

2. The method according to claim 1, wherein the sample data of the power battery comprises: a plurality of sets of data for a same model of the power battery under a plurality of vehicle driving conditions.

3. The method according to claim 1, wherein the dividing, by a processor, the sample data into a plurality of categories comprises:
selecting a clustering algorithm, and determining clustering parameters in the clustering algorithm;
categorizing each point of the sample data as a core point or a boundary point of a cluster according to the clustering parameters; and
configuring the categories according to the core point, and dividing the sample data into the categories.

4. The method according to claim 3, wherein
the clustering algorithm comprises a Density-Based Spatial Clustering of Applications with Noise (DBSCAN) algorithm; and
the clustering parameters comprise a radius of neighborhood and a neighborhood count threshold.

5. The method according to claim 1, wherein the feature identifier comprises a clustering center; and
the selecting, by the processor, an aging model corresponding to the battery state parameters from a plurality of aging models comprises:
calculating a distance between the battery state parameters and a clustering center corresponding to each of the categories; and
selecting an aging model having a shortest distance as the aging model corresponding to the battery state parameters.

6. The method according to claim 1, wherein the fitting relationship comprises polynomial fitting, neural network fitting, or regression tree fitting.

7. The method according to claim 1, wherein the battery state parameters comprise: at least two of a current, a voltage, a temperature, state of charge, storage time, a depth of discharge, and coulombic efficiency.

8. A device for obtaining a capacity of a power battery, comprising:
at least one processor; and a memory coupled with the at least one processor, wherein
the memory stores instructions, and when the instructions are executed by the at least one processor, the instructions cause the at least one processor to perform operations comprising:
collecting, by sensors, sample data of the power battery;
dividing the sample data into a plurality of categories, each of the categories having a corresponding aging model and a feature identifier, the feature identifier identifying features of sample data of a corresponding category, and the aging model being obtained by: determining a fitting relationship in the aging model, and determining parameters in the fitting relationship according to sample data of a corresponding type of the aging model;
acquiring battery state parameters of the power battery;
selecting an aging model from a plurality of aging models according to the battery state parameters; and
inputting the battery state parameters into the selected aging model to obtain the capacity of the power battery.

9. The device according to claim 8, wherein the sample data of the power battery comprises: a plurality of sets of data for a same model of the power battery under a plurality of vehicle driving conditions.

10. The device according to claim 8, wherein the dividing the sample data into a plurality of categories comprises:
selecting a clustering algorithm, and determining clustering parameters in the clustering algorithm;
categorizing each point of the sample data as a core point or a boundary point of a cluster according to the clustering parameters; and
configuring the categories according to the core point, and dividing the sample data into the categories.

11. The device according to claim 10, wherein
the clustering algorithm comprises a Density-Based Spatial Clustering of Applications with Noise (DBSCAN) algorithm; and
the clustering parameters comprise a radius of neighborhood and a neighborhood count threshold.

12. The device according to claim 8, wherein the feature identifier comprises a clustering center; and
the selecting, by the processor, an aging model corresponding to the battery state parameters from a plurality of aging models comprises:
calculating a distance between the battery state parameters and a clustering center corresponding to each of the categories; and
selecting an aging model having a shortest distance as the aging model corresponding to the battery state parameters.

13. The device according to claim 8, wherein the fitting relationship comprises polynomial fitting, neural network fitting, or regression tree fitting.

14. The device according to claim 8, wherein the battery state parameters comprise: at least two of a current, a voltage, a temperature, state of charge, storage time, a depth of discharge, and coulombic efficiency.

15. A non-transitory computer-readable storage medium, storing a computer program, wherein the computer program, when executed by a processor, causes the processor to perform operations comprising:
collecting, by sensors, sample data of a power battery;
dividing the sample data into a plurality of categories, each of the categories having a corresponding aging model and a feature identifier, the feature identifier identifying features of sample data of a corresponding category, and the aging model being obtained by: determining a fitting relationship in the aging model, and determining parameters in the fitting relationship according to sample data of a corresponding type of the aging model;
acquiring battery state parameters of the power battery;
selecting an aging model from a plurality of aging models according to the battery state parameters; and
inputting the battery state parameters into the selected aging model to obtain a capacity of the power battery.

16. The medium according to claim 15, wherein the sample data of the power battery comprises: a plurality of sets of data for a same model of the power battery under a plurality of vehicle driving conditions.

17. The medium according to claim 15, wherein the dividing the sample data into a plurality of categories comprises:
selecting a clustering algorithm, and determining clustering parameters in the clustering algorithm;
categorizing each point of the sample data as a core point or a boundary point of a cluster according to the clustering parameters; and
configuring the categories according to the core point, and dividing the sample data into the categories.

18. The medium according to claim 17, wherein
the clustering algorithm comprises a Density-Based Spatial Clustering of Applications with Noise (DBSCAN) algorithm; and
the clustering parameters comprise a radius of neighborhood and a neighborhood count threshold.

19. The medium according to claim 15, wherein the feature identifier comprises a clustering center; and
the selecting, by the processor, an aging model corresponding to the battery state parameters from a plurality of aging models comprises:
calculating a distance between the battery state parameters and a clustering center corresponding to each of the categories; and
selecting an aging model having a shortest distance as the aging model corresponding to the battery state parameters.

20. The medium according to claim 15, wherein the fitting relationship comprises polynomial fitting, neural network fitting, or regression tree fitting.
